(19) United States
(12) Patent Application Publication
(10) Pub. No.: US 2014/0252343 A1
(43) Pub. Date: Sep. 11, 2014

(54) THIN-FILM TRANSISTOR ACTIVE DEVICE AND METHOD FOR MANUFACTURING SAME

(71) Applicant: Shenzhen China Star Optoelectronics Technology Co., Ltd., Shenzhen, Guangdong (CN)

(72) Inventors: Chenglung Chiang, Shenzhen (CN); Polin Chen, Shenzhen (CN)

(73) Assignee: Shenzhen China Star Optoelectronics Technology Co., Ltd., Shenzhen, Guangdong (CN)

(21) Appl. No.: 13/806,821

(22) PCT Filed: Oct. 24, 2012
(86) PCT No.: PCT/CN2012/083390

§ 371 Date: Dec. 24, 2012

(30) Foreign Application Priority Data
Oct. 9, 2012 (CN) 201210381032.1

(51) Int. Cl. H01L 27/12

(52) U.S. Cl. CPC H01L 27/1225; H01L 27/127
USPC 257/43; 438/104

(57) ABSTRACT

The present invention provides a thin-film transistor active device and a method for manufacturing the device. The thin-film transistor active device includes a substrate and a plurality of thin-film transistors formed on the substrate. Each of thin-film transistors includes a gate insulation layer and an oxide semiconductor active layer. The gate insulation layer is a silicon oxide layer having refractivity between 1.43-1.47. During the formation of the gate insulation layer, the flowrate ration between nitrous oxide and silicon tetrahydride in chemical vapor deposition is controlled to be greater than 30% so as to control the refractivity of the gate insulation layer so formed of silicon oxide to be between 1.43-1.47; meanwhile, the content of N—H bond in the gate insulation layer is reduced so as to effectively prevent the high interface trap density between the gate insulation layer and the oxide semiconductor layer caused by high content of N—H bond.

### BACKGROUND OF THE INVENTION

1. Field of the Invention

The present invention relates to the technical field of flat panel display, and in particular to a thin-film transistor (TFT) active device and a method for manufacturing the TFT active device.

2. The Related Arts

An active matrix flat panel display device has numerous advantages, such as thin device body, less power consumption, and being free of radiation, and is thus widely used. Most of the flat panel display devices available in the market are backlighting liquid crystal displays, which comprise a liquid crystal display panel and a backlight module. The operation principle of the liquid crystal display panel is that liquid crystal molecules are arranged between two parallel glass substrates and electricity is selectively applied to the glass substrates to cause change of the orientation of the liquid crystal molecules in order to refract out the light from a backlight module for formation of an image.

A liquid crystal display panel is composed of a color filter (CF) substrate, a thin-film transistor (TFT) substrate, liquid crystal (LC) interposed between the CF substrate and the TFT substrate, and a sealant. A general manufacturing process comprises a front stage of array process (including thin film, yellow light, etching, and film stripping), an intermediate stage of cell process (including bonding TFT substrate and the CF substrate), and a rear stage of assembling process (including mounting drive ICs and printed circuit board). The front stage of array process generally makes the TFT substrate for controlling the movement of liquid crystal molecules. The intermediate stage of cell process generally introduces liquid crystal between the TFT substrate and the CF substrate. The rear stage of assembling process generally mounts the drive ICs and combining the printed circuit board to effect driving the liquid crystal molecules to rotate for displaying images.

The TFT substrate generally comprises a glass substrate and TFTs formed on the glass substrate. The TFTs are subjected to at least six masking processes before they can be formed on the glass substrate.

Referring to FIGS. 1A-1F, a flow of a conventional manufacture process of a TFT is illustrated. IGZO is an abbreviation standing for indium gallium zinc oxide, which is a technique of oxide thin-film transistor comprising forming a metal oxide active layer on a gate insulation layer of the transistor, this being a TFT driving technique. According to the flow of manufacturing process illustrated in FIGS. 1A-1F, a gate electrode (GE) 101 is first formed on a substrate 100. Next, a gate insulation (GI) layer 102 is formed to cover the gate electrode 101. Then, an oxide semiconductor layer, which is specifically an IGZO layer 103, is formed on the gate insulation layer 101. Then, a first protection layer (an ES layer) 104 is formed on IGZO layer 103. The ES layer is often formed through chemical vapor deposition (CVD) of a precursor substance. Afterwards, a source terminal 105 and a drain terminal 106 are formed of a sputtered metal layer. In addition to the source terminal 105 and the drain terminal 106, the metal layer also serves as wiring lay-out material connecting to the IGZO layer 103. A conventional manufacturing process is to deposit the metal on the IGZO layer 103 and subjects the metal to etching to form the source electrode and the drain electrode. Then, a second protection layer (a PV layer) 107 is formed to cover the source terminal 105 and the drain terminal 106. To this point, a TFT active device that is generally composed of a gate electrode 101, a gate insulation layer 102, an IGZO layer 103, a first protection layer 104, a source terminal 105, a drain terminal 106, and a second protection layer 107 is formed.

### SUMMARY OF THE INVENTION

An object of the present invention is to provide a thin-film transistor active device, wherein a gate insulation layer of a thin-film transistor has a low content of N—H bond so as to prevent deterioration of the electrical property of the thin-film transistor.

Another object of the present invention is to provide a method for manufacturing thin-film transistor active device, which controls the flowrate ratio between nitrous oxide and silicon tetrahydride in forming a gate insulation layer of the thin-film transistor active device to be greater than 30% to make the refractivity of the gate insulation layer between 1.43-1.47 so as to effectively reduce the content of N—H bond in the gate insulation layer to thereby improve the quality of the thin-film transistor active device.

To achieve the objective, the present invention provides a thin-film transistor active device, which comprises a substrate and a plurality of thin-film transistors formed on the substrate. Each of thin-film transistors comprises a gate insulation layer and an oxide semiconductor active layer. The gate insulation layer comprises a silicon oxide layer having refractivity between 1.43-1.47.

The thin-film transistor comprises a gate terminal. The gate insulation layer is formed on the gate terminal through chemical vapor deposition.

In the chemical vapor deposition of the gate insulation layer, flowrate ratio between nitrous oxide and silicon tetrahydride is greater than 30%.

The oxide semiconductor active layer comprises at least one of zinc oxide, tin oxide, indium oxide, and gallium oxide and is formed on the gate insulation layer through sputtering.

The thin-film transistor also comprises a first protection layer formed on the oxide semiconductor active layer and the first protection layer is formed through chemical vapor deposition on the oxide semiconductor active layer.

The thin-film transistor also comprises a source terminal and a drain terminal formed on the first protection layer. The source terminal and the drain terminal are formed by sputtering metal on the first protection layer to form a metal layer, which is then subjected to a masking operation. The metal layer comprising one of a molybdenum layer, an aluminum layer, a titanium layer, and a copper layer or a lamination thereof.

The thin-film transistor also comprises a second protection layer formed on the source terminal and the drain terminal. The second protection layer is formed through chemical vapor deposition on the source terminal and the drain terminal.

The present invention also provides a thin-film transistor active device, which comprises a substrate and a plurality of thin-film transistors formed on the substrate, each of thin-film transistors comprising a gate insulation layer and an oxide semiconductor active layer, the gate insulation layer comprising a silicon oxide layer having a refractivity between 1.43-1.47;

wherein the thin-film transistor comprises a gate terminal, the gate insulation layer being formed on the gate terminal through chemical vapor deposition;

wherein in the chemical vapor deposition of the gate insulation layer, flowrate ratio between nitrous oxide and silicon tetrahydride is greater than 30%;

wherein the oxide semiconductor active layer comprises at least one of zinc oxide, tin oxide, indium oxide, and gallium oxide and is formed on the gate insulation layer through sputtering;

wherein the thin-film transistor also comprises a first protection layer formed on the oxide semiconductor active layer and the first protection layer is formed through chemical vapor deposition on the oxide semiconductor active layer;

wherein the thin-film transistor also comprises a source terminal and a drain terminal formed on the first protection layer, the source terminal and the drain terminal being formed by sputtering metal on the first protection layer to form a metal layer, which is then subjected to a masking operation, the metal layer comprising one of a molybdenum layer, an aluminum layer, a titanium layer, and a copper layer or a lamination thereof; and

wherein the thin-film transistor also comprises a second protection layer formed on the source terminal and the drain terminal, the second protection layer being formed through chemical vapor deposition on the source terminal and the drain terminal.

The present invention also provides a method for manufacturing thin-film transistor active device, which comprises the following steps:

(1) providing a substrate;

(2) forming a gate terminal on the substrate through sputtering and a masking operation;

(3) forming a gate insulation layer on the gate terminal through chemical vapor deposition, wherein the chemical vapor deposition is carried out with a flowrate ration between nitrous oxide and silicon tetrahydride greater than 30% and the refractivity of the gate insulation layer so formed is between 1.43-1.47;

(4) forming an oxide semiconductor layer on the gate insulation layer through sputtering and a masking operation;

(5) forming a first protection layer on the oxide semiconductor active layer through chemical vapor deposition and a masking operation;

(6) forming a metal layer on the first protection layer through a sputtering operation and applying a masking operation to form a source terminal and a drain terminal;

(7) forming a second protection layer on the metal layer and forming a bridging hole in the second protection layer; and

(8) forming a transparent conductive layer on the second protection layer through sputtering deposition and a masking operation so as to form a thin-film transistor active device.

The gate terminal comprises one of a molybdenum layer, an aluminum layer, a titanium layer, and a copper layer or a lamination thereof.

The oxide semiconductor active layer comprises at least one of zinc oxide, tin oxide, indium oxide, and gallium oxide.

The metal layer comprises one of a molybdenum layer, an aluminum layer, a titanium layer, and a copper layer or a lamination thereof.

The transparent conductive layer comprises one of an indium tin oxide layer, an indium zinc oxide layer, an aluminum zinc oxide layer, and a gallium zinc oxide or a lamination thereof.

The efficacy of the present invention is that the present invention provides a thin-film transistor active device and a method for manufacturing the thin-film transistor active device, wherein during the formation of a gate insulation layer of the thin-film transistor, the flowrate ration between nitrous oxide and silicon tetrahydride in the chemical vapor deposition is controlled to be greater than 30% so as to control the refractivity of the gate insulation layer so formed of silicon oxide to be between 1.43-1.47; meanwhile, the content of N—H bond in the gate insulation layer is reduced so as to effectively prevent the high interface trap density between the gate insulation layer and the oxide semiconductor layer caused by excessively high content of N—H bond in the gate insulation layer and thus effectively prevent deterioration of electrical property of the oxide TFT and improve the quality of the thin-film transistor active device.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, of the present invention will be apparent from the following detailed description of an embodiment of the present invention, with reference to the attached drawings. In the drawings:

FIGS. 1A-1F illustrate a flow for manufacturing a thin-film transistor with a conventional manufacture process;

FIG. 2 is a schematic view showing the structure of a thin-film transistor active device according to the present invention;

FIG. 3 is a plot showing the relationship between the flowrate ratio between nitrous oxide and silicon tetrahydride in forming a gate insulation layer with chemical vapor deposition and the ratio between hydrogen and silicon contained in the gate insulation layer so formed;

FIG. 4 is a plot showing the relationship between the flowrate ratio between nitrous oxide and silicon tetrahydride in forming a gate insulation layer with chemical vapor deposition and the refractivity of the gate insulation layer so formed; and

FIG. 5 is a flow chart illustrating a method for manufacturing a thin-film transistor active device according to the present invention.

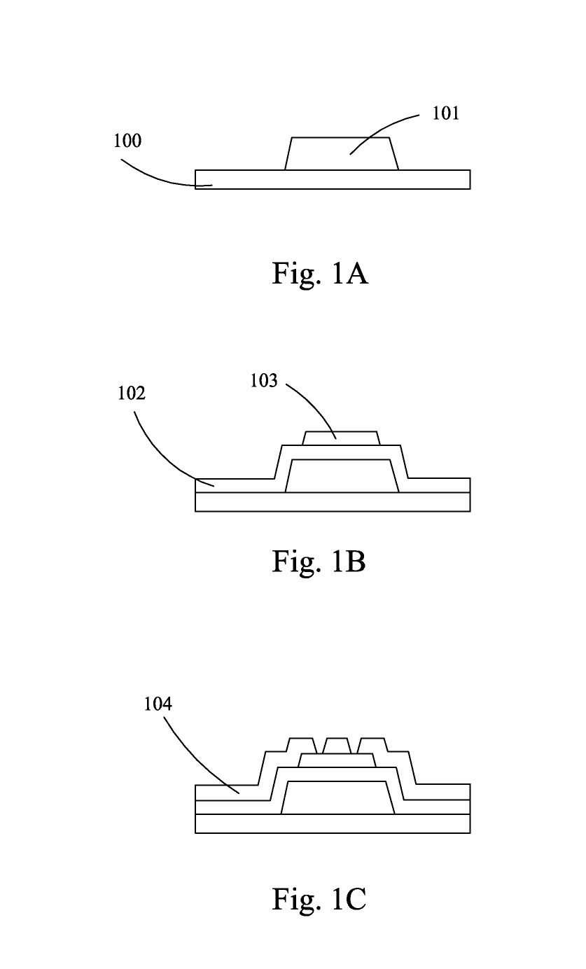

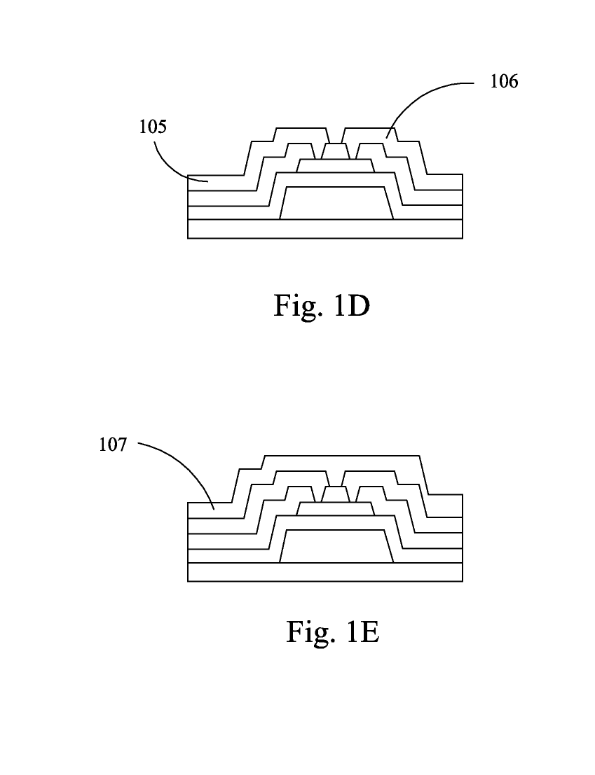

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

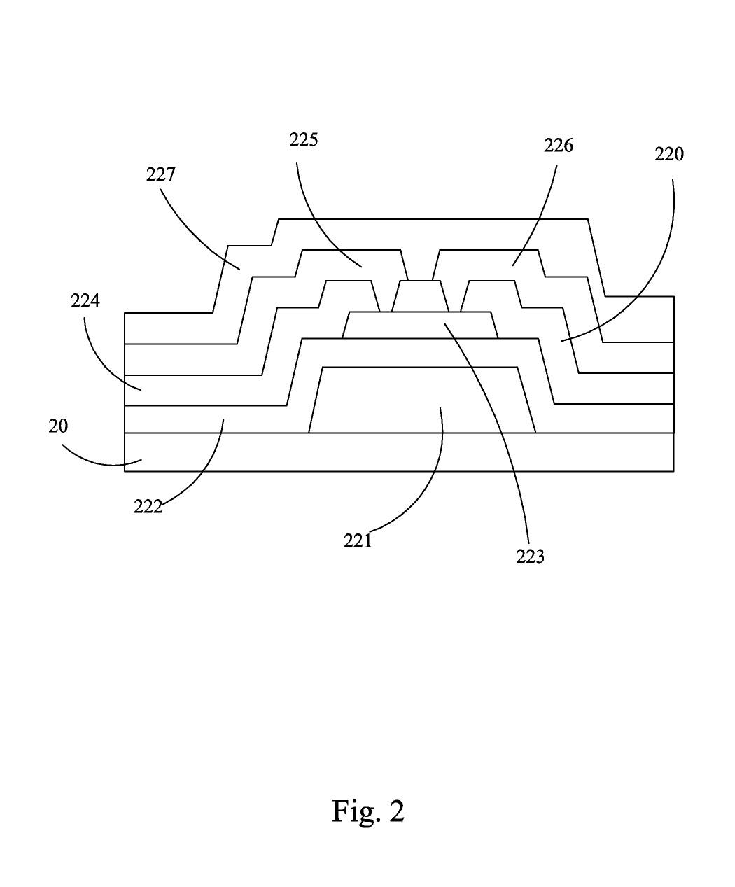

Referring to FIGS. 2-4, the present invention provides a thin-film transistor active device, which comprises a substrate 20 and a plurality of thin-film transistors 220 formed on the substrate. Each of the thin-film transistors 220 comprises a gate terminal 221 and a gate insulation layer 222 formed on the gate terminal 221. The gate insulation layer 222 comprises a silicon oxide layer, which is formed on the gate terminal 221 through chemical vapor deposition. The thin-film transistor 220 also comprises an oxide semiconductor active layer 223 formed on the gate insulation layer 222. The oxide semiconductor active layer 223 comprises at least one of zinc oxide, tin oxide, indium oxide, and gallium oxide and is formed on the gate insulation layer 222 through sputtering.

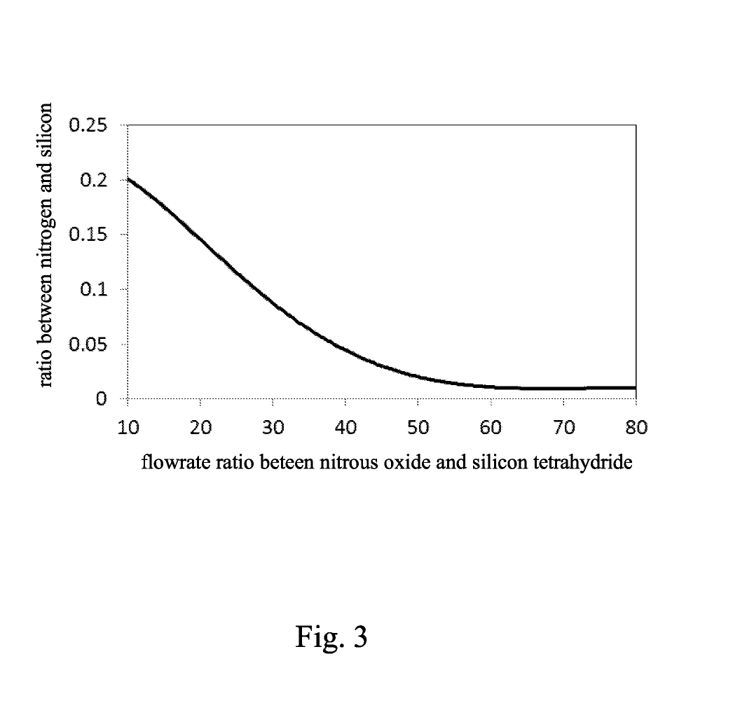

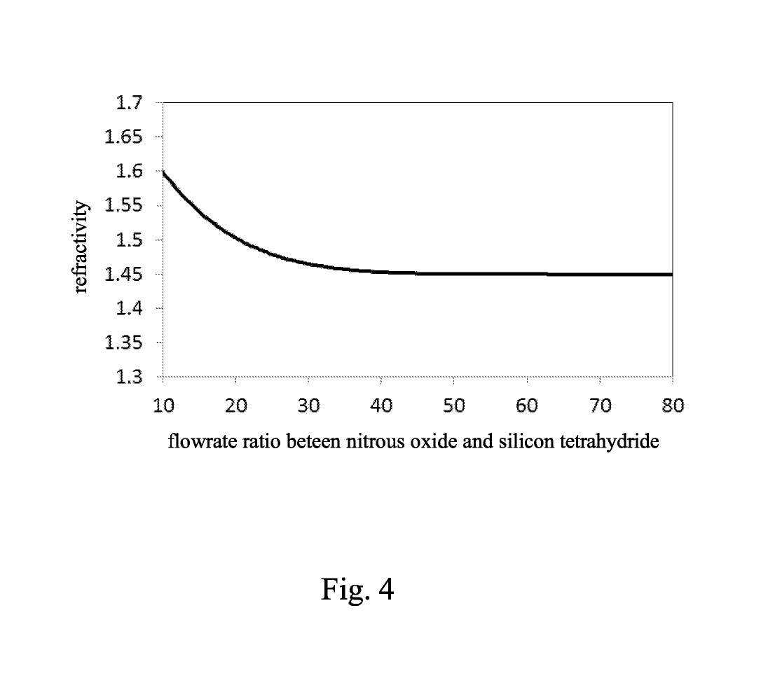

Referring to FIGS. 3 and 4, in forming the gate insulation layer through chemical vapor deposition, flowrate ratio between nitrous oxide and silicon tetrahydride has a significant influence on the property of the gate insulation layer so formed and the most significant is the content of N—H bond of the gate insulation layer so formed. When the content of N—H bond is great, the interface trap density between the gate insulation layer and the oxide semiconductor active layer would be great. This causes deterioration of electrical property of the thin-film transistor so formed and thus reduces the quality of the entire thin-film transistor active device.

It can be seen from FIG. 3 that when the flowrate ratio between nitrous oxide and silicon tetrahydride is greater than 30%, it is advantageous for the ratio between nitrogen and silicon contained in the gate insulation layer formed through chemical vapor deposition to get less than 0.1 thereby lowering the content of N—H bond in the gate insulation layer and thus effectively preventing deterioration of electrical property of the thin-film transistor active device so formed.

It can be seen from FIG. 4 that when the flowrate ratio between nitrous oxide and silicon tetrahydride is greater than 30%, the refractivity of the gate insulation layer formed through chemical vapor deposition is between 1.43-1.47 and under this condition, the content of N—H bond in the gate insulation layer is relatively low so as to effectively prevent deterioration of electrical property of the thin-film transistor active device so formed.

In the present invention, in forming the gate insulation layer 222 through chemical vapor deposition, the flowrate ratio between nitrous oxide and silicon tetrahydride is set greater than 30% and the refractivity of the gate insulation layer so formed is controlled to be between 1.43-1.47.

The thin-film transistor 220 also comprises a first protection layer 224 formed on the oxide semiconductor active layer 223 and the first protection layer is formed through chemical vapor deposition on the oxide semiconductor active layer 223.

The thin-film transistor 220 also comprises a source terminal 225 and a drain terminal 226 formed on the first protection layer 224. The source terminal 225 and the drain terminal 226 are formed by sputtering metal on the first protection layer 224 to form a metal layer, which is then subjected to a masking operation.

The metal layer comprises one of a molybdenum layer, an aluminum layer, a titanium layer, and a copper layer or a lamination thereof.

The thin-film transistor 220 also comprises a second protection layer 227 formed on the source terminal 225 and the drain terminal 226. The second protection layer is formed through chemical vapor deposition on the source terminal 225 and the drain terminal 226.

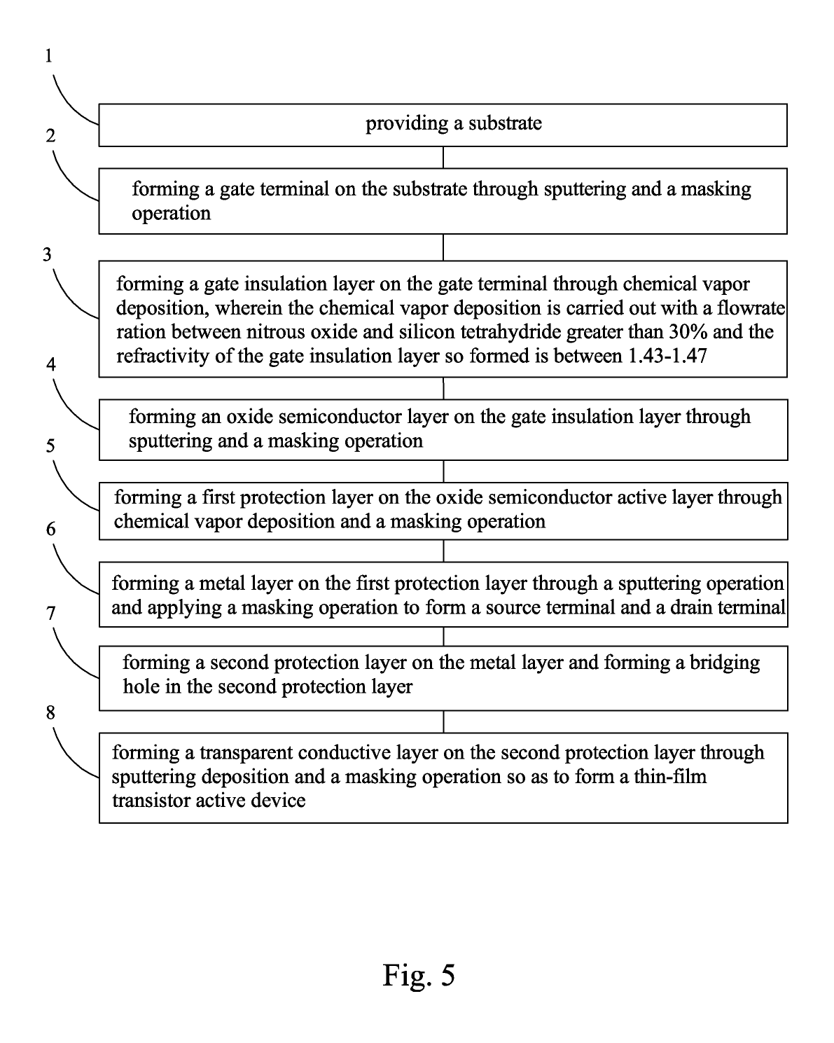

Referring to FIG. 5, the present invention also provides a method for manufacturing a thin-film transistor active device, which comprises the following steps:

Step 1: providing a substrate.

Step 2: forming a gate terminal on the substrate through sputtering and a masking operation.

The gate terminal comprises one of a molybdenum layer, an aluminum layer, a titanium layer, and a copper layer or a lamination thereof.

Step 3: forming a gate insulation layer on the gate terminal through chemical vapor deposition, wherein the chemical vapor deposition is carried out with a flowrate ration between nitrous oxide and silicon tetrahydride greater than 30% and the refractivity of the gate insulation layer so formed is between 1.43-1.47.

Step 4: forming an oxide semiconductor active layer on the gate insulation layer through sputtering deposition and a masking operation.

The oxide semiconductor active layer comprises at least one of zinc oxide, tin oxide, indium oxide, and gallium oxide.

Step 5: forming a first protection layer on the oxide semiconductor active layer through chemical vapor deposition and a masking operation.

Step 6: forming a metal layer on the first protection layer through a sputtering operation and applying a masking operation to form a source terminal and a drain terminal.

The metal layer comprises one of a molybdenum layer, an aluminum layer, a titanium layer, and a copper layer or a lamination thereof.

Step 7: forming a second protection layer on the metal layer and forming a bridging hole in the second protection layer.

Step 8: forming a transparent conductive layer on the second protection layer through sputtering deposition and a masking operation so as to form a thin-film transistor active device.

The transparent conductive layer is one of an indium tin oxide layer, an indium zinc oxide layer, an aluminum zinc oxide layer, and a gallium zinc oxide layer or a lamination thereof.

In summary, the present invention provides a thin-film transistor active device and a method for manufacturing the thin-film transistor active device, wherein during the formation of a gate insulation layer of the thin-film transistor, the flowrate ration between nitrous oxide and silicon tetrahydride in the chemical vapor deposition is controlled to be greater than 30% so as to control the refractivity of the gate insulation layer so formed of silicon oxide to be between 1.43-1.47; meanwhile, the content of N—H bond in the gate insulation layer is reduced so as to effectively prevent the high interface trap density between the gate insulation layer and the oxide semiconductor layer caused by excessively high content of N—H bond in the gate insulation layer and thus effectively prevent deterioration of electrical property of the oxide TFT and improve the quality of the thin-film transistor active device.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A thin-film transistor active device, comprising a substrate and a plurality of thin-film transistors formed on the substrate, each of thin-film transistors comprising a gate insulation layer and an oxide semiconductor active layer, the gate insulation layer comprising a silicon oxide layer having refractivity between 1.43-1.47.

2. The thin-film transistor active device as claimed in claim 1, wherein the thin-film transistor comprises a gate terminal, the gate insulation layer being formed on the gate terminal through chemical vapor deposition.

3. The thin-film transistor active device as claimed in claim 2, wherein in the chemical vapor deposition of the gate insulation layer, flowrate ratio between nitrous oxide and silicon tetrahydride is greater than 30%.

4. The thin-film transistor active device as claimed in claim 1, wherein the oxide semiconductor active layer comprises at least one of zinc oxide, tin oxide, indium oxide, and gallium oxide and is formed on the gate insulation layer through sputtering.

5. The thin-film transistor active device as claimed in claim 1, wherein the thin-film transistor also comprises a first protection layer formed on the oxide semiconductor active layer and the first protection layer is formed through chemical vapor deposition on the oxide semiconductor active layer.

6. The thin-film transistor active device as claimed in claim 1, wherein the thin-film transistor also comprises a source terminal and a drain terminal formed on the first protection layer, the source terminal and the drain terminal being formed by sputtering metal on the first protection layer to form a metal layer, which is then subjected to a masking operation, the metal layer comprising one of a molybdenum layer, an aluminum layer, a titanium layer, and a copper layer or a lamination thereof.

7. The thin-film transistor active device as claimed in claim 1, wherein the thin-film transistor also comprises a second protection layer formed on the source terminal and the drain terminal, the second protection layer being formed through chemical vapor deposition on the source terminal and the drain terminal.

8. A thin-film transistor active device, comprising a substrate and a plurality of thin-film transistors formed on the substrate, each of thin-film transistors comprising a gate insulation layer and an oxide semiconductor active layer, the gate insulation layer comprising a silicon oxide layer having a refractivity between 1.43-1.47;
wherein the thin-film transistor comprises a gate terminal, the gate insulation layer being formed on the gate terminal through chemical vapor deposition;
wherein in the chemical vapor deposition of the gate insulation layer, flowrate ratio between nitrous oxide and silicon tetrahydride is greater than 30%;
wherein the oxide semiconductor active layer comprises at least one of zinc oxide, tin oxide, indium oxide, and gallium oxide and is formed on the gate insulation layer through sputtering;
wherein the thin-film transistor also comprises a first protection layer formed on the oxide semiconductor active layer and the first protection layer is formed through chemical vapor deposition on the oxide semiconductor active layer;
wherein the thin-film transistor also comprises a source terminal and a drain terminal formed on the first protection layer, the source terminal and the drain terminal being formed by sputtering metal on the first protection layer to form a metal layer, which is then subjected to a masking operation, the metal layer comprising one of a molybdenum layer, an aluminum layer, a titanium layer, and a copper layer or a lamination thereof; and
wherein the thin-film transistor also comprises a second protection layer formed on the source terminal and the drain terminal, the second protection layer being formed through chemical vapor deposition on the source terminal and the drain terminal.

9. A method for manufacturing thin-film transistor active device, comprising the following steps:
(1) providing a substrate;
(2) forming a gate terminal on the substrate through sputtering and a masking operation;
(3) forming a gate insulation layer on the gate terminal through chemical vapor deposition, wherein the chemical vapor deposition is carried out with a flowrate ration between nitrous oxide and silicon tetrahydride greater than 30% and the refractivity of the gate insulation layer so formed is between 1.43-1.47;
(4) forming an oxide semiconductor layer on the gate insulation layer through sputtering and a masking operation;
(5) forming a first protection layer on the oxide semiconductor active layer through chemical vapor deposition and a masking operation;
(6) forming a metal layer on the first protection layer through a sputtering operation and applying a masking operation to form a source terminal and a drain terminal;
(7) forming a second protection layer on the metal layer and forming a bridging hole in the second protection layer; and
(8) forming a transparent conductive layer on the second protection layer through sputtering deposition and a masking operation so as to form a thin-film transistor active device.

10. The method for manufacturing thin-film transistor active device as claimed in claim 9, wherein the gate terminal comprises one of a molybdenum layer, an aluminum layer, a titanium layer, and a copper layer or a lamination thereof.

11. The method for manufacturing thin-film transistor active device as claimed in claim 9, wherein the oxide semiconductor active layer comprises at least one of zinc oxide, tin oxide, indium oxide, and gallium oxide.

12. The method for manufacturing thin-film transistor active device as claimed in claim 9, wherein the metal layer comprises one of a molybdenum layer, an aluminum layer, a titanium layer, and a copper layer or a lamination thereof.

13. The method for manufacturing thin-film transistor active device as claimed in claim 9, wherein the transparent conductive layer comprises one of an indium tin oxide layer, an indium zinc oxide layer, an aluminum zinc oxide layer, and a gallium zinc oxide or a lamination thereof.
